(19) United States
(12) Patent Application Publication
(10) Pub. No.: US 2026/0286510 A1
(43) Pub. Date: Sep. 24, 2026

(54) Plasma and Photon assisted Metal-Organic Chemical Vapor Deposition

(71) Applicant: Xuejun Xie, Palo Alto, CA (US)

(72) Inventor: Xuejun Xie, Palo Alto, CA (US)

(73) Assignee: PhantaField Inc., Palo Alto, CA (US)

(21) Appl. No.: 19/087,523

(22) Filed: Mar. 23, 2025

(51) Int. Cl. C23C 16/18; C23C 16/458; C23C 16/46; C23C 16/48; C23C 16/505; H01J 37/32

(52) U.S. Cl. CPC C23C 16/18; C23C 16/4584; C23C 16/46; C23C 16/48; C23C 16/505; H01J 37/32357; H01J 2237/3321; H01J 2237/3323

(57) ABSTRACT

A Plasma and Photon Assisted Metal-Organic Chemical Vapor Deposition (PP-MOCVD) system for low-temperature deposition of semiconductor materials is disclosed. The system integrates a remote plasma chamber to pre-decompose high decomposition temperature precursors, a direct injection system for low-temperature precursors, a UV light source to eliminate carbon residuals and remove defects, and a rotating susceptor for uniform deposition. This method enables high-growth-rate, low-defect-density synthesis of III-V semiconductors or 2D materials, facilitating advanced semiconductor applications.

### BACKGROUND OF THE INVENTION

Metal-Organic Chemical Vapor Deposition (MOCVD) is a widely utilized technique for the deposition of thin films, particularly in semiconductor manufacturing. However, conventional MOCVD methods necessitate high operating temperatures, which present challenges in the growth of delicate materials, including III-V compounds and two-dimensional (2D) semiconductors. Elevated temperatures are incompatible with complementary metal-oxide-semiconductor (CMOS) backend processes, introduce material stress, and limit potential applications.

Efforts to reduce the growth temperature in MOCVD have encountered multiple challenges, including defect formation, residual carbon contamination, and significantly lower growth rates. Defects such as trap states degrade electronic and optical properties, while carbon residues compromise material purity and device performance. A primary challenge remains in achieving low-temperature growth while maintaining high deposition rates and minimal defect densities.

The present invention addresses these issues by incorporating plasma-assisted and photon-assisted methodologies into the MOCVD process. The plasma-assisted technique reduces precursor decomposition temperatures, facilitating low-temperature deposition, while the photon-assisted technique mitigates residual carbon and defects under low-temperature conditions, thereby improving material quality. The combination of these approaches enables a highly efficient, low-temperature growth process.

### BRIEF SUMMARY OF THE INVENTION

The present invention discloses a Plasma and Photon Assisted Metal-Organic Chemical Vapor Deposition (PP-MOCVD) system designed to enable low-temperature deposition of semiconductor materials with high growth rates and reduced defect densities. The system integrates a remote plasma chamber for precursor decomposition and a UV light source for the removal of residual carbon and defect states during film growth. A rotating susceptor ensures uniform deposition across the substrate. This methodology is particularly beneficial for the synthesis of III-V materials and 2D semiconductors, offering a novel solution for achieving high-quality films compatible with backend semiconductor processing.

### BRIEF DESCRIPTION OF DRAWINGS

FIG. 1: A schematic representation of the PP-MOCVD system, illustrating the remote plasma power source (102), remote plasma chamber (109), plasma-activated precursor inlet (101), direct precursor inlet (103), UV light source (104), light source purge gas inlet (106), wafer loading port (105), and rotating susceptor (108).

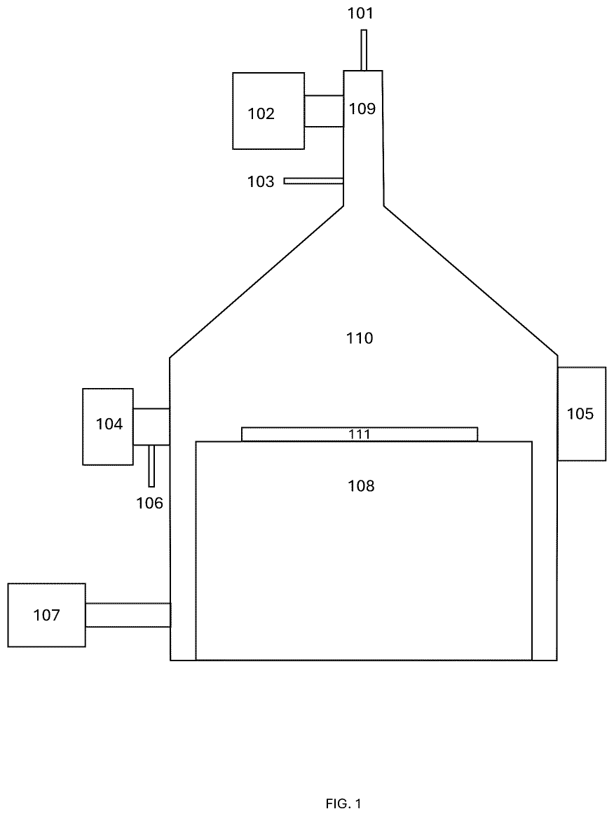

FIG. 2: A top-down view of the PP-MOCVD system, depicting the placement of the UV light source (104), wafer loading port (105), and rotating susceptor (108).

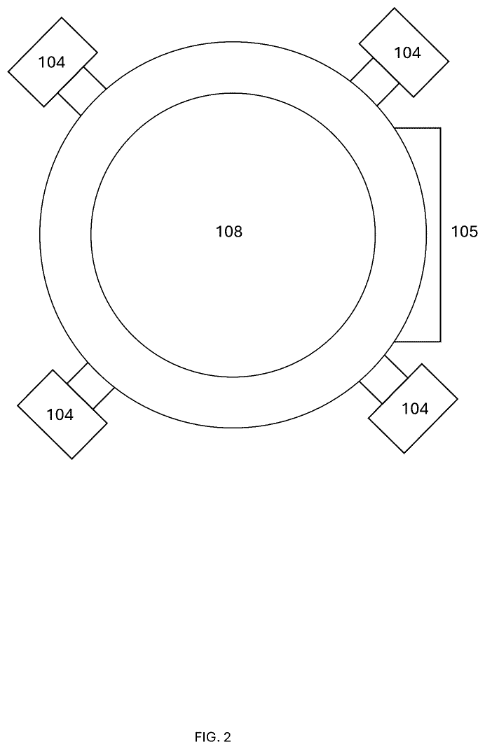

FIG. 3: An alternative schematic of the PP-MOCVD system, featuring an up-down movable rotating susceptor (301).

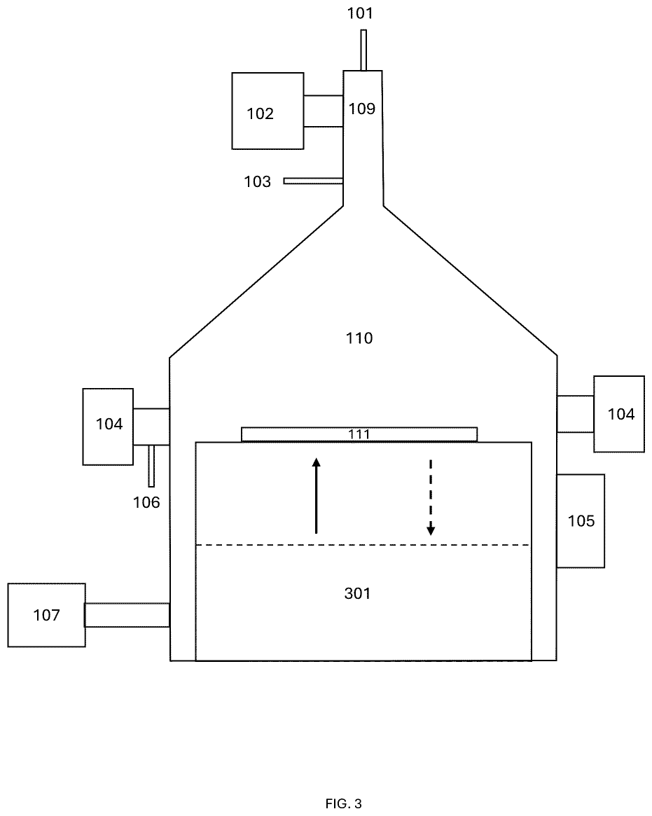

FIG. 4: An alternative top-down view of the PP-MOCVD system, demonstrating the placement of the UV light source (104), wafer loading port (105), and movable rotating susceptor (301).

### DETAILED DESCRIPTION OF THE INVENTION

The PP-MOCVD system integrates plasma-assisted precursor decomposition and photon-assisted defect reduction within a traditional MOCVD framework. The system comprises:
Gas Delivery System: A gas inlet (101) for high decomposition temperature precursor gases such as H₂S, H₂Se, NH₃, Ga(CH₃)₃ or alternative precursors delivered with carrier gases including Ar, H₂, or N₂. A precursor inlet (103) supplying W(CO)₆, Mo(CO)₆, AsH₃ or alternative precursors with carrier gases including Ar, H₂, or N₂.
Remote Plasma Chamber (109): Utilizes RF power (102) to partially decompose high decomposition temperature precursors, enhancing their reactivity at lower temperatures.
Reaction Chamber (110): Facilitates precursor reaction and thin film deposition.
Rotating Heated Susceptor (108): Supports the substrate (111) and ensures uniform deposition.
UV Light Source (104): Positioned at an optimized angle to irradiate the deposition zone through the chamber walls, facilitating carbon removal and defect reduction.
Purging Gas System (106): Prevents precursor interference near the UV light source, ensuring an uncontaminated optical environment.

The remote plasma chamber (109) utilizes RF power (102) to initiate partial decomposition and activation of high decomposition temperature precursors such as H₂S, H₂Se, NH₃, Ga(CH₃)₃ or alternative precursors delivered with carrier gases including Ar, H₂, or N₂. This plasma-assisted process significantly lowers precursor decomposition temperatures, enabling deposition conditions that are compatible with CMOS backend process. The decomposed precursors are transported into the reaction chamber using carrier gases, which regulate flow rates and maintain homogeneous distribution and uniform flow.

A UV light source (104) is optimally positioned to irradiate the deposition zone and the rotating susceptor (108). The high-energy UV photons effectively break down residual carbon from metal-organic precursors such as W(CO)₆, Mo(CO)₆, Ga(CH₃)₃ or alternative precursors, thereby enhancing film purity. Additionally, UV exposure mitigates defect formation by eliminating unwanted trap centers, leading to improved electronic and optical properties. To prevent precursor gas from contaminating the UV source, a purging gas (106) is introduced to maintain a clear optical path.

The rotating susceptor (108) holds the substrate (111) and rotates continuously to ensure uniform film growth. The rotation enhances precursor distribution uniformity, preventing localized depletion. The susceptor temperature is precisely controlled to optimize material crystallinity, and rotation speed can be adjusted based on deposition conditions. The UV light projection and the rotating susceptor provide uniform exposure to the substrate (111).

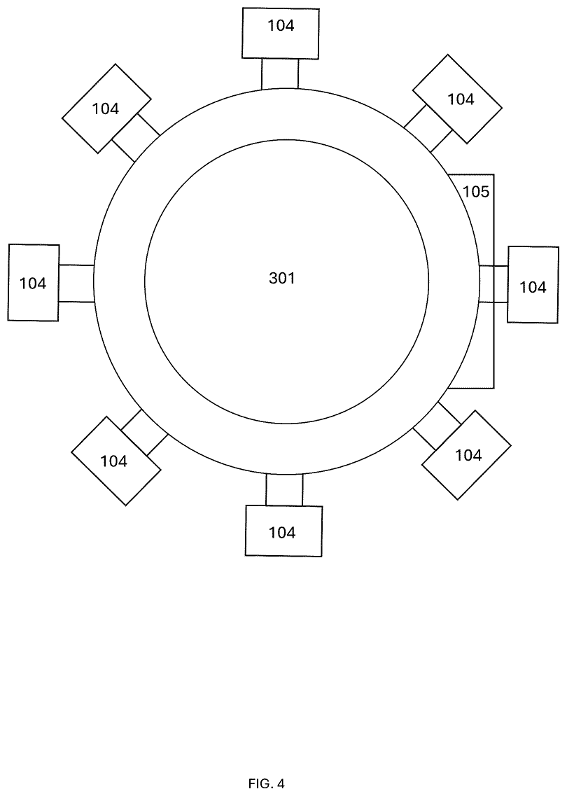

In an alternative configuration, the rotating susceptor (301) may be lowered to the loading port (105) allowing more UV light units (104), as depicted in FIG. 4, facilitating higher production speeds and better uniformity.

A pump (107) regulates system pressure and removes byproducts, thereby preventing contamination and ensuring a controlled deposition environment.

1. A Plasma and Photon Assisted Metal-Organic Chemical Vapor Deposition system comprising:
A remote plasma chamber configured to pre-decompose a high decomposition temperature precursor gas before introducing it into a deposition chamber;
A direct precursor injection system for other precursors;
UV light sources positioned to illuminate the substrate for the removal of carbon residuals and defects;
A rotating susceptor to ensure uniform deposition across the substrate surface.

2. The system of claim 1, wherein the remote plasma chamber assisted decomposition reduces the activation energy of precursor gases, enabling low-temperature growth.

3. The system of claim 1, wherein the UV light source operates at a wavelength suitable for removing carbon residuals and defects.

4. The system of claim 1, wherein the rotating susceptor is controlled to maintain uniform thermal distribution and film thickness.

5. The system of claim 1, wherein the rotating susceptor can be moved up and down for wafer loading allowing more UV light sources.
